(19) United States
(12) Patent Application Publication
(10) Pub. No.: US 2015/0255331 A1
(43) Pub. Date: Sep. 10, 2015

(54) INTEGRATED CIRCUITS WITH A COPPER AND MANGANESE COMPONENT AND METHODS FOR PRODUCING SUCH INTEGRATED CIRCUITS

(71) Applicant: GLOBALFOUNDRIES, Inc., Grand Cayman (KY)

(72) Inventors: Xunyuan Zhang, Albany, NY (US); Hoon Kim, Clifton Park, NY (US); Moosung M. Chae, Englewood Cliffs, NJ (US)

(73) Assignee: GLOBALFOUNDRIES, Inc., Grand Cayman (KY)

(21) Appl. No.: 14/196,842

(22) Filed: Mar. 4, 2014

(51) Int. Cl. H01L 21/768; H01L 23/482; H01L 23/48

(52) U.S. Cl. CPC H01L 21/76843; H01L 21/76802; H01L 21/76876; H01L 23/481; H01L 23/4827

(57) ABSTRACT

Integrated circuits with copper and magnesium components and methods for producing such integrated circuits are provided. A method of producing the integrated circuits includes forming an aperture in an interlayer dielectric. A seed layer is formed in the aperture, where the seed layer includes manganese and copper, and where the seed layer has a copper concentration gradient. A core is formed overlying the seed layer, where the core includes copper.

### TECHNICAL FIELD

The technical field generally relates to integrated circuits and methods for producing integrated circuits, and more particularly relates to integrated circuits with a copper and manganese seed layer and a copper core within an aperture and methods for producing such integrated circuits.

### BACKGROUND

Integrated circuits utilize copper components as a conductive material for several different types of structures, such as interconnects and contacts. A copper core is typically deposited over a dielectric material, and a seed layer including manganese, an adhesion layer, and other layers are formed between the copper core and the dielectric. The seed layer and the copper core are deposited in separate process steps, and the integrated circuit is often transported from one manufacturing process to the next between the process steps. Manganese oxidizes rapidly, and manganese oxide in the seed layer decreases conduction and forms a weaker bond with the copper core than manganese that has not oxidized. Short exposure to oxygen, such as exposure to air during transport from the seed layer deposition process to the copper core deposition process, is sufficient to cause undesired oxidation of the manganese.

Manganese and copper will diffuse when heated, and the manganese tends to diffuse to the outer surface of the seed layer or other manganese containing component while the copper tends to diffuse into the interlayer dielectric. Copper that diffuses into the interlayer dielectric reduces the amount of copper in the conductive component, and increases the conduction of the dielectric material, both of which are undesirable. The manganese that diffuses to the outer surface is more readily exposed to the atmosphere and oxidized.

Accordingly, it is desirable to provide a manganese seed layer, where the manganese is protected from the atmosphere to minimize oxidation yet concentrated adjacent to the dielectric material to form a strong bond. It is also desirable to provide methods for producing such integrated circuits. In addition, it is desirable to provide a seed layer that blocks diffusion of copper into the dielectric material, yet still forms a strong bond with the dielectric. Furthermore, other desirable features and characteristics of the present embodiment will become apparent from the subsequent detailed description and the appended claims, taken in conjunction with the accompanying drawings and this background of the invention.

### BRIEF SUMMARY

Integrated circuits and methods for producing the same are provided. In an exemplary embodiment, a method for producing an integrated circuit includes forming an aperture in an interlayer dielectric. A seed layer is formed in the aperture, where the seed layer includes manganese and copper, and where the seed layer has a copper concentration gradient. A core is formed overlying the seed layer, where the core includes copper.

In another embodiment, a method is provided for producing an integrated circuit. An aperture is formed in an interlayer dielectric, and a core that includes copper is formed in the aperture. Diffusion of the copper from the core into the interlayer dielectric is limited by a seed layer positioned between the core and the interlayer dielectric, where the seed layer includes a manganese silicate barrier.

An integrated circuit is provided in another embodiment. The integrated circuit includes an interlayer dielectric with an aperture therein. A seed layer directly contacts the interlayer dielectric within the aperture, where about 90 mass percent or more of the seed layer is manganese and copper, and where the seed layer has a copper concentration gradient. A core overlies the seed layer, where the core includes copper.

### BRIEF DESCRIPTION OF THE DRAWINGS

The present embodiments will hereinafter be described in conjunction with the following drawing figures, wherein like numerals denote like elements, and wherein:

FIGS. 1-3 and 5-7 illustrate, in cross sectional views, a portion of an integrated circuit and methods for its fabrication in accordance with exemplary embodiments; and

FIG. 4 illustrates a perspective sectional view of a portion of the integrated circuit illustrated in FIG. 3.

### DETAILED DESCRIPTION

The following detailed description is merely exemplary in nature and is not intended to limit the various embodiments or the application and uses thereof. Furthermore, there is no intention to be bound by any theory presented in the preceding background or the following detailed description.

The various embodiments of the integrated circuits described herein include a manganese- and copper-containing seed layer that prevents oxidation and copper diffusion so problematic in the prior art. Integrated circuits often include conductive components made from copper. In an exemplary embodiment, a conductive component includes a core and a seed layer formed in an aperture within an interlayer dielectric. The aperture can be a via for a contact, a trench for an interconnect, or other openings for conductive copper components. The seed layer is deposited within the aperture, where the seed layer has a concentration gradient of copper and manganese. The manganese concentration at the interlayer dielectric and seed layer interface is about 100 mass percent, and the copper concentration at the core and seed layer interface is about 100 mass percent, with copper and manganese concentration gradients between the two interfaces. Because about 100 percent copper is present at the core/seed layer interface, essentially no manganese is oxidized when the core surface is exposed to oxygen in the atmosphere. In turn, the interlayer dielectric includes silicon in many embodiments, and the manganese reacts with the silicon to form manganese silicate at the interface between the seed layer and the interlayer dielectric. The manganese silicate forms a barrier that limits or prevents diffusion of copper, so very little or no copper diffuses into the interlayer dielectric. The concentration gradient in the manganese and copper seed layer provides a protective shell of copper to limit oxidation of the manganese while also forming a manganese silicate barrier to limit copper diffusion into the interlayer dielectric.

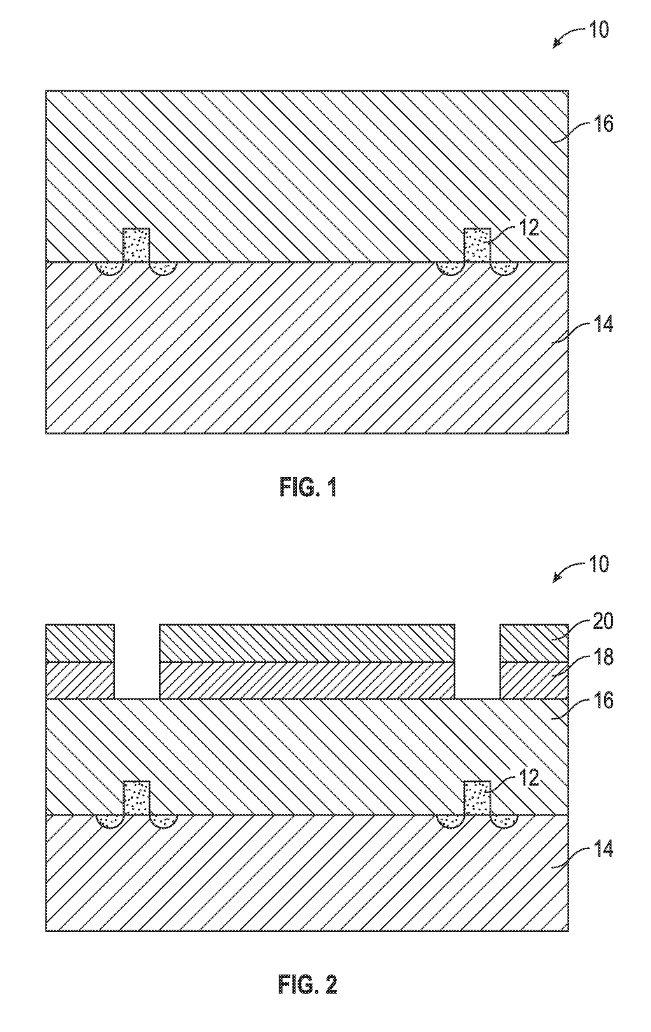

Referring to FIG. 1, in accordance with an exemplary embodiment, an integrated circuit 10 includes an electronic component 12 overlying a substrate 14. As used herein, the term “overlying” means “over” such that an intervening layer may lie between the electronic component 12 and the substrate 14, and “on” such that the electronic component 12 physically contacts the substrate 14. As used herein, the term “substrate” 14 will be used to encompass semiconductor materials conventionally used in the semiconductor industry from which to make electrical devices. Semiconductor materials include monocrystalline silicon materials, such as the relatively pure or lightly impurity-doped monocrystalline silicon materials typically used in the semiconductor industry, as well as polycrystalline silicon materials, and silicon admixed with other elements such as germanium, carbon, and the like. Semiconductor materials also include other materials such as relatively pure and impurity-doped germanium, gallium arsenide, zinc oxide, glass, and the like. In an exemplary embodiment, the semiconductor material is a monocrystalline silicon substrate. The silicon substrate may be a bulk silicon wafer (as illustrated) or may be a thin layer of semiconductor on an insulating layer (commonly known as semiconductor-on-insulator or SOI) that, in turn, is supported by a carrier wafer.

A wide variety of electronic components 12 can be used. A partial list of potential electronic components 12 includes various types of transistors, resistors, capacitors, etc. FIG. 1 illustrates, in an exemplary embodiment, a field effect transistor, but other types of electronic components 12 are also possible. Electronic components 12 are produced by a wide variety of methods, and the means of production of the electronic components are not critical to this description. A variety of different types of electronic components 12 are included in many integrated circuits, so one integrated circuit may include several different types of electronic components 12, and electrical connections can be made between different and/or similar types of electronic components 12.

An interlayer dielectric 16 is formed overlying the substrate 14 and the electronic component 12. The interlayer dielectric 16 is an electrically insulating material that covers the electronic component 12 and the substrate 14, and may cover other components such as a shallow trench isolation (not shown). In an exemplary embodiment, the interlayer dielectric 16 includes silicon, such as silicon oxide which can be deposited by chemical vapor deposition using tetraethylorthosilicate (TEOS). In alternate embodiments, other deposition techniques are used, and other insulating materials can also be used, including but not limited to silicon nitride and silicon oxynitride.

Reference is now made to FIG. 2. In an exemplary embodiment, an optional hard mask 18 is formed overlying the interlayer dielectric 16. The hard mask 18 may be formed of silicon nitride, which can be deposited by low pressure chemical vapor deposition using ammonia and dichlorosilane. A photoresist layer 20 is formed overlying the hard mask 18 and the interlayer dielectric 16, and the photoresist layer 20 is patterned and developed to expose selected locations. The photoresist layer 20 is deposited by spin coating, and patterned by exposure to light or other electromagnetic radiation through a mask with transparent sections and opaque sections. The light causes a chemical change in the photoresist such that either the exposed portion or the non-exposed portion can be selectively removed. Selected locations of the photoresist layer 20 are removed with an organic solvent, and remaining portions of the photoresist layer 20 overlie other areas of the hard mask 18 and interlayer dielectric 16. The hard mask 18 is etched to expose portions of the interlayer dielectric 16, where the photoresist layer 20 serves as an etch mask for the hard mask 18. A hard mask 18 formed of silicon nitride can be etched with a plasma etch using nitrogen trifluoride in a hydrogen ambient.

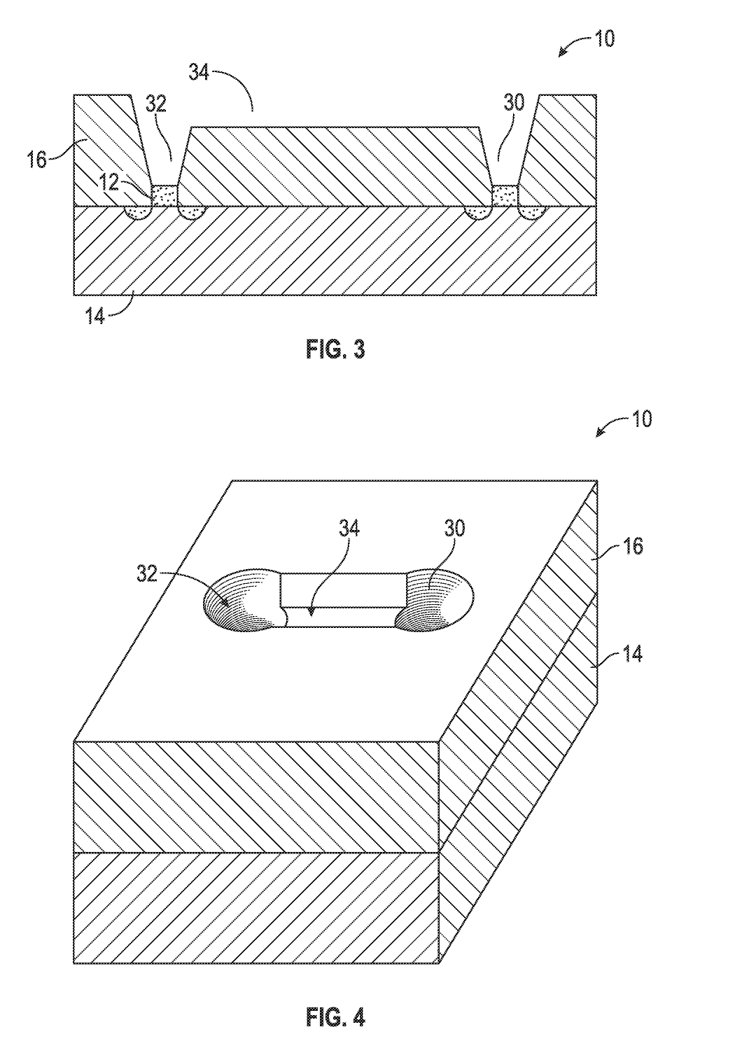

An aperture 30 is formed in or through the interlayer dielectric 16, as illustrated in FIGS. 3 and 4 with continuing reference to FIG. 2. The aperture 30 may be a via 32 that extends through the interlayer dielectric 16 to contact the electronic component 12, the substrate 14, or the like, or the aperture 30 may be a trench 34 that extends into the interlayer dielectric 16 but does not penetrate it. The aperture 30 can be formed by an anisotropic etch, and the etchant is selective to the material of the interlayer dielectric 16 over the material of the hard mask 18. In some embodiments, the etchant is selective to the material of the interlayer dielectric 16 over the material of the substrate 14 or the material of the electronic component 12. For example, the via 32 extends through the interlayer dielectric 16 to contact the electronic component 12, so an etchant selective to the interlayer dielectric 16 over the material of the electronic component 12 will remove the interlayer dielectric 16 without damaging the electronic component 12. In an exemplary embodiment, the interlayer dielectric 16 is silicon dioxide, the hard mask 18 is silicon nitride, and a plasma etch is used. There are plasma etchants that are selective to silicon dioxide over silicon nitride, such as hydrofluoric acid. The photoresist layer 20 may be removed before or after the aperture 30 is formed in various embodiments, where the patterned hard mask 18 is in place in embodiments where the photoresist layer 20 is removed before the etch. FIG. 4 illustrates two vias 32 extending through the interlayer dielectric 16, and a trench 34 formed between the two vias 32 in the interlayer dielectric 16. The remaining FIGS. illustrate an aperture 30 that is a via, but the description is equally applicable to a trench 34 that does not penetrate the interlayer dielectric 16.

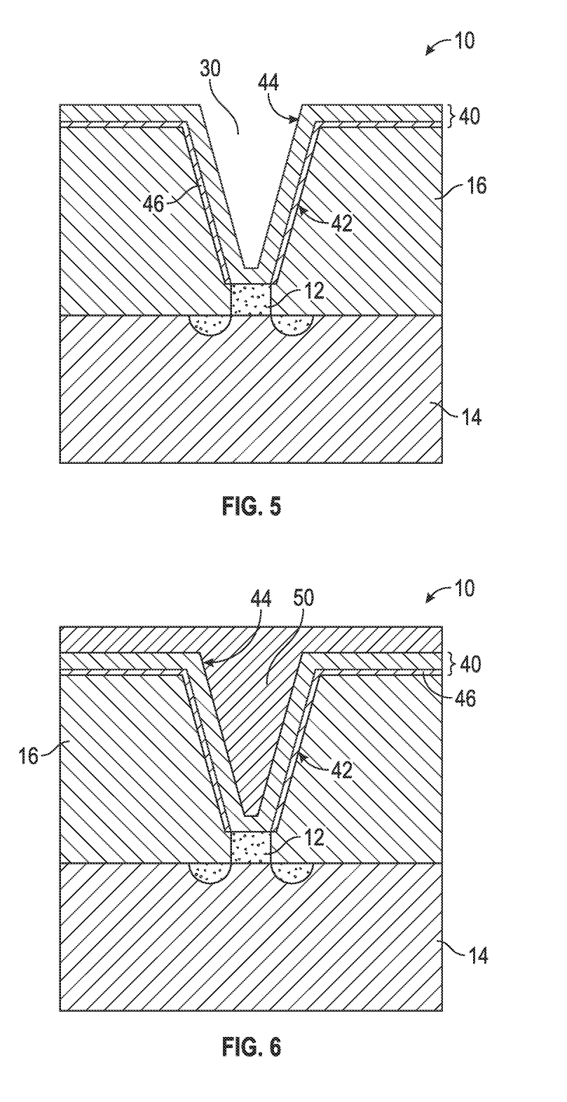

Reference is now made to the exemplary embodiment illustrated in FIG. 5. A seed layer 40 is formed in the aperture 30 and overlying the substrate 14. In some embodiments, the seed layer 40 is formed in direct contact with the interlayer dielectric 16, so an interlayer dielectric surface 42 of the seed layer 40 directly contacts the interlayer dielectric 16. The seed layer 40 also has a core surface 44 opposite the interlayer dielectric surface 42. The seed layer 40 includes copper and manganese, and is formed with a copper concentration gradient such that the concentration of copper is higher at or near the core surface 44 than at or near the interlayer dielectric surface 42. In some embodiments, copper is deposited at a copper concentration of about 10 mass percent or less at the interlayer dielectric surface 42, and about 90 mass percent or greater at the core surface 44. In a similar manner, manganese is deposited at a manganese concentration of about 90 mass percent or more at the interlayer dielectric surface 42, and about 10 mass percent or less at the core surface 44. In other embodiments, the copper is deposited at about 1 mass percent or less and manganese is deposited at about 99 mass percent or greater at the interlayer dielectric surface 42, and copper is deposited at about 99 mass percent or greater and manganese is deposited at about 1 mass percent or less at the core surface 44. Other alloy materials may be present in the seed layer 40, but in some embodiments the seed layer 40 is primarily copper and manganese, such that the seed layer 40 is about 90 mass percent or more copper and manganese. In an exemplary embodiment, about a 3-5 nanometer (nm) seed layer 40 is deposited by chemical vapor deposition at about 100 degrees centigrade (° C.) to about 300° C. using manganese amidinate and copper amidinate, where the concentration of the manganese and copper amidinate is ramped during the deposition processes to form the concentration gradient. Other manganese and/or copper compounds can also be used for the deposition process, but oxygen containing compounds are generally avoided to minimize the formation of manganese oxide. The manganese amidinate is initially present at about 90 to about 100 percent during the deposition, and is gradually replaced to produce a final concentration of about 90 to about 100 mass percent copper amidinate. In an alternate embodiment, the seed layer 40 is formed by atomic layer deposition.

The manganese in the seed layer 40 reacts with silicon in the interlayer dielectric 16 to form a manganese silicate barrier 46 at the interlayer dielectric surface 42. In the embodiment illustrated, the seed layer 40 directly contacts the electronic component 12, but the manganese does not react with the material of the electronic component 12. The electronic component 12 may have a metal silicide surface in some embodiments, but the manganese does not form manganese silicate with a metal silicide because manganese is generally not reactive enough to replace the metal in the metal silicide. Therefore, there is essentially no manganese silicate barrier 46 at the intersection of the seed layer 40 and the electronic component 12. Manganese silicate is not a good electrical conductor, so the absence of manganese silicate at the interface between the seed layer 40 and the electronic component 12 aids in the formation of a good electrical connection. The manganese silicate barrier 46 blocks or slows the diffusion of copper, so copper in the seed layer 40 or otherwise within the aperture 30 does not significantly diffuse into the interlayer dielectric 16. The high concentration of manganese deposited at the interlayer dielectric surface 42 produces an essentially continuous manganese silicate barrier 46, so higher initial deposition concentrations of manganese in the seed layer 40 provide a better copper diffusion barrier. Manganese will diffuse toward the core surface 44 upon annealing, but the manganese silicate does not significantly diffuse so the manganese silicate barrier 46 remains in place to block copper diffusion upon annealing.

Manganese adheres strongly to the interlayer dielectric 16, so the high concentration of manganese at the interlayer dielectric surface 42 produces a strong bond between the seed layer 40 and the interlayer dielectric 16. Manganese reacts with silicon, so the concentration of manganese at the interlayer dielectric surface 42 can vary because silicon is incorporated into the manganese silicate barrier 46 of the seed layer 40. Copper adheres to the manganese and manganese silicate, but copper does not adhere well to silicon dioxide or most other silicon-containing materials commonly used for an interlayer dielectric 16. The low concentration of copper at the interlayer dielectric surface 42 aids in the formation of a strong bond between the seed layer 40 and the interlayer dielectric 16. The manganese concentration is about 10 mass percent or less at the core surface 44, and in some embodiments about 1 mass percent or less, so very little to no manganese is exposed to the atmosphere at the core surface 44. Copper is present at high concentrations at the core surface 44, but copper does not oxidize as readily as manganese so the seed layer 40 can be exposed to air for several hours without any significant oxidation.

Referring now to FIG. 6, a core 50 is formed overlying the seed layer 40, where the core 50 includes copper. In some embodiments, the core 50 is primarily copper, with a copper concentration of 80 mass percent or more. In other embodiments, the core 50 is 99 mass percent copper or more, and essentially no manganese is deposited within the core 50. Some manganese may diffuse into the core 50 upon annealing in some embodiments, but in other embodiments the core 50 is essentially free of manganese, with a manganese concentration of about 0.1 mass percent or less. The core 50 may include copper alloys in some embodiments, but the copper alloys do not include manganese in many embodiments. The core 50 is a good electrical conductor because of the high concentration of copper. In an exemplary embodiment, the core 50 directly contacts the core surface 44 of the seed layer 40. The core 50 adheres well to the seed layer 40 because the core surface 44 of the seed layer 40 and the core 50 are both primarily copper. Therefore, the copper gradient in the seed layer 40 results in a strong bond between the core 50 and the interlayer dielectric 16.

The core 50 can be deposited in a variety of manners, including chemical vapor deposition or copper electroplating. In some embodiments, iodine is deposited on the core surface 44 of the seed layer 40 prior to deposition of the core 50 to help prevent or minimize the formation of voids. In an exemplary embodiment, ethyl iodine vapor is fed directly over the seed layer 40 and the integrated circuit 10 without a carrier gas, and thereby deposited. The core 50 is then formed by chemical vapor deposition of copper using copper (N,N′-di-sec-butylacetamidinate) dimer The iodine acts as a surfactant and a catalyst, and sinks to the bottom of the aperture 30 as the deposition proceeds. The iodine floats over the deposited copper, so the iodine remains active during the entire deposition process. This increases the rate of deposition from the bottom of the aperture 30, so the core 50 fills the open space of the aperture 30 with substantially no voids, even when high aspect apertures 30 are employed. The iodine can also be deposited before copper electroplating, if desired.

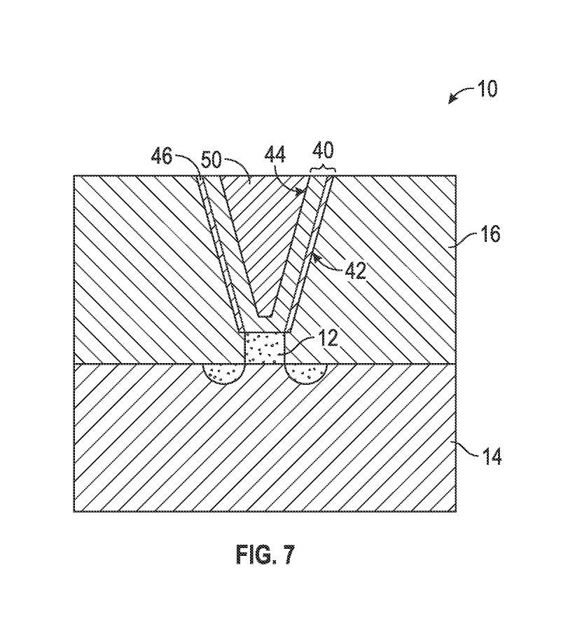

FIG. 7 illustrates an exemplary embodiment where overburden from the seed layer 40 and the core 50 are removed. The overburden can be removed by chemical mechanical planarization, so the upper surface of the interlayer dielectric 16 is exposed and accessible. The electrically conductive core 50 is formed and secured in place within the interlayer dielectric 16, and can be used to produce electrical connections between various electronic components 12 to produce an integrated circuit 10, as understood by those skilled in the art.

While at least one exemplary embodiment has been presented in the foregoing detailed description, it should be appreciated that a vast number of variations exist. It should also be appreciated that the exemplary embodiments are only examples, and are not intended to limit the scope, applicability, or configuration of the application in any way. Rather, the foregoing detailed description will provide those skilled in the art with a convenient road map for implementing one or more embodiments, it being understood that various changes may be made in the function and arrangement of elements described in an exemplary embodiment without departing from the scope, as set forth in the appended claims.

What is claimed is:

1. A method for producing an integrated circuit comprising:
forming an aperture in an interlayer dielectric;
forming a seed layer in the aperture, wherein the seed layer comprises manganese and copper, and wherein the seed layer has a copper concentration gradient; and
forming a core overlying the seed layer, wherein the core comprises copper.

2. The method of claim 1 wherein forming the seed layer further comprises forming the seed layer with the copper concentration gradient, wherein the seed layer has a copper concentration of about 10 mass percent or less at an interlayer dielectric surface facing the interlayer dielectric, and the copper concentration is about 90 mass percent or more at a core surface facing the core.

3. The method of claim 1 wherein forming the seed layer further comprises forming the seed layer with an interlayer dielectric surface directly contacting the interlayer dielectric and a core surface directly contacting the core.

4. The method of claim 1 wherein forming the seed layer further comprises forming the seed layer from copper and manganese such that the seed layer comprises about 90 mass percent or more copper and manganese.

5. The method of claim 4 wherein forming the seed layer further comprises forming the seed layer in direct contact with the interlayer dielectric in the aperture.

6. The method of claim 5 wherein forming the core further comprises forming the core in direct contact with the seed layer.

7. The method of claim 1 wherein forming the aperture in the interlayer dielectric further comprises forming the aperture in the interlayer dielectric wherein the interlayer dielectric comprises silicon.

8. The method of claim 7 wherein forming the seed layer in the aperture further comprises forming the seed layer such that a magnesium silicate barrier is formed at an interlayer dielectric surface of the seed layer, wherein the interlayer dielectric surface contacts the interlayer dielectric.

9. The method of claim 1 wherein forming the aperture further comprises forming the aperture such that the aperture extends to an electronic component underlying the interlayer dielectric.

10. The method of claim 1 wherein forming the seed layer in the aperture further comprises forming the seed layer by chemical vapor deposition.

11. A method of producing an integrated circuit comprising:
forming an aperture in an interlayer dielectric;
forming a core in the aperture, wherein the core comprises copper; and
limiting diffusion of the copper from the core into the interlayer dielectric with a seed layer positioned between the core and the interlayer dielectric, wherein the seed layer comprises a manganese silicate barrier.

12. The method of claim 11 further comprising:
forming the seed layer within the aperture prior to forming the core, wherein the seed layer is formed with a copper concentration gradient.

13. The method of claim 12 wherein forming the seed layer further comprises forming the seed layer with the copper concentration gradient, wherein a seed layer copper concentration is about 10 mass percent or less at an interlayer dielectric surface facing the interlayer dielectric, and the seed layer copper concentration is about 90 mass percent or more at a core surface facing the core.

14. The method of claim 12 wherein forming the seed layer further comprises forming the seed layer from about 90 mass percent or more of copper and manganese, and wherein the seed layer directly contacts the interlayer dielectric.

15. The method of claim 11 wherein limiting diffusion of copper from the core into the interlayer dielectric further comprises depositing the seed layer by atomic vapor deposition.

16. The method of claim 11 wherein forming the core further comprises:
depositing the core by chemical vapor deposition.

17. The method of claim 16 further comprising:
depositing iodine on the seed layer prior to forming the core.

18. The method of claim 11 wherein forming the aperture in the interlayer dielectric further comprises forming the aperture in the interlayer dielectric wherein the interlayer dielectric comprises silicon.

19. The method of claim 18 wherein limiting diffusion of copper from the core into the interlayer dielectric with the seed layer further comprises reacting manganese from the seed layer with silicon from the interlayer dielectric to form the manganese silicate barrier.

20. An integrated circuit comprising:
an interlayer dielectric having an aperture therein;
a seed layer directly contacting the interlayer dielectric within the aperture, wherein about 90 mass percent or more of the seed layer comprises manganese and copper, and wherein the seed layer comprises a copper concentration gradient; and
a core overlying the seed layer, wherein the core comprises copper.
